(19) United States
(12) Patent Application Publication
(10) Pub. No.: US 2013/0181342 A1
(43) Pub. Date: Jul. 18, 2013

(54) SEMICONDUCTOR PACKAGE

(71) Applicant: Sung-Kyu Park, Hwaseong-si (KR)

(72) Inventor: Sung-Kyu Park, Hwaseong-si (KR)

(73) Assignee: SAMSUNG ELECTRONICS CO., LTD., Suwon-si (KR)

(21) Appl. No.: 13/613,408

(22) Filed: Sep. 13, 2012

(30) Foreign Application Priority Data
Jan. 18, 2012 (KR) 10-2012-0005769

(51) Int. Cl. H01L 23/498

(52) U.S. Cl. 257/737; 257/777; 257/E23.06; 257/E23.01

(57) ABSTRACT

A semiconductor package includes a substrate having first and second surfaces which face each other, a semiconductor chip mounted on the first surface, a first encapsulant formed on the first surface and at least partially encapsulating the semiconductor chip. A second encapsulant is formed on the second surface and first external connection terminals formed on the second surface to penetrate the second encapsulant. The external connection terminals have first ends in contact with the second surface. Second external connection terminals are attached to second ends of the first external connection terminals.

This application claims priority from Korean Patent Application No. 10-2012-0005769 filed on Jan. 18, 2012 in the Korean Intellectual Property Office, the disclosure of which is incorporated herein by reference in its entirety.

### BACKGROUND

1. Field of Inventive Concepts

Inventive concepts relate to semiconductor packaging.

2. Description of the Related Art

Low-profile semiconductor packages may be used to reduce the volume and mass of semiconductor devices and systems. A low-profile semiconductor package may be implemented using an encapsulant to, for example, mold a surface with epoxy molding compound (EMC). Although relatively light and compact, such packages may experience warpage due to mismatches between the coefficients of thermal expansion (CTE) of a semiconductor substrate and the epoxy molding compound. Such warpage may cause, or contribute to, failure of the packaged semiconductor device.

### SUMMARY

In an exemplary embodiment in accordance with principles of inventive concepts, a semiconductor chip may be mounted on one side of a substrate, with electrical connection made to wiring within the substrate through connection terminals. The connection terminals may be implemented as conductive balls situated on ball lands formed in the substrate, for example. Connection terminals on the opposite side of the substrate may provide electrical communication between external circuitry and the semiconductor chip through wiring in the substrate, to the connection terminals on the semiconductor side of the substrate, and, through those connection terminals, to circuitry within the semiconductor chip. The substrate may include an insulating layer, with embedded wiring, and solder mask layers on either side of the insulating layer. The solder mask layers may be formed to allow electrical connection between connection terminals on either side of the substrate.

In an exemplary embodiment in accordance with principles of inventive concepts, the semiconductor chip and substrate upon which it is mounted may be encapsulated, for example, by two layers of material, one or both of which may include, or substantially constitute, epoxy molding compound (EMC). The upper layer of encapsulant material may completely surround the semiconductor chip or it may be flush with the upper surface of the semiconductor chip, leaving the top surface of the chip exposed, for example. The lower layer of encapsulant material may be thinner than the upper layer and may leave a portion of the lower connection terminals exposed, to allow for connection to external circuitry, for example.

The lower connection terminals may be formed of a plurality of conductive balls and may make contact with electrical wiring in the substrate through ball lands, as the upper connection terminals may similarly make contact with electrical wiring in the substrate. In an exemplary embodiment in accordance with principles of inventive concepts, the lower connection terminal may include two conductive balls, with the uppermost of the two having a relatively flat surface on top to allow for good contact with ball lands and a relatively flat surface on the bottom to allow for good contact with a second conductive ball. The lower of the two conductive balls may have a relatively flat top surface to allow for good contact with the first conductive ball. Because the lower connection terminal includes a plurality of conductive balls, the width of the terminals may be less than would otherwise be required for a contact terminal of the same height but made of a single conductive ball. Such a single-orb connection terminal would tend to have a broad waste region, as opposed to the relatively narrow, concave, region created by joining two conductive balls. As a result, lower connection terminals may be packed more closely than they might otherwise be packed.

The lower encapsulant layer in accordance with principles of inventive concepts may extend only part of the way along the length of the lower connection terminal: to the joint between two conductive balls that form the lower connection terminal, for example. In accordance with principles of inventive concepts, encapsulant layers on either side of the substrate operate to counterbalance thermal effects on the semiconductor packaging. That is, with the upper and lower encapsulation layers having similar thermal coefficients of expansion, warpage that might otherwise occur, with only one side of the semiconductor package encapsulated, for example, may be avoided.

A semiconductor package in accordance with principles of inventive concepts may include a substrate having first and second surfaces which face each other; a first semiconductor chip mounted on the first surface; a first encapsulant formed on the first surface and encapsulating at least a portion of the first semiconductor chip; a second encapsulant formed on the second surface; first external connection terminals formed on the second surface to penetrate the second encapsulant and having first ends in contact with the second surface; and second external connection terminals attached to second ends of the first external connection terminals, respectively.

The second encapsulant may have first and second surfaces which face each other, wherein the first encapsulant surface contacts the second substrate surface, and the distance from the second substrate surface to the second encapsulant surface is substantially equal to the distance from the second substrate surface to the second ends of the first external connection terminals. Side surfaces of the first external connection terminals are surrounded by the second encapsulant, and side surfaces of the second external connection terminals are clear of the second encapsulant.

The substrate may include a ball land formed on the second surface, wherein the first end of a first external connection terminal contacts the ball land and the first and second external connection terminals are stacked sequentially on the ball land and the second end of a first external connection terminal may be a flat surface.

The side surfaces of the first external connection terminals and the side surfaces of the second external connection terminals may be linked to form uneven shapes. The substrate may include a solder resist layer formed on the second surface, and the first and second encapsulants may contain epoxy molding compound (EMC).

In accordance with principles of inventive concepts, the semiconductor package may include a second semiconductor chip formed on the second surface, wherein the second semiconductor chip is encapsulated by the second encapsulant and the first encapsulant may be thicker than the second encapsulant. The first and second external connection terminals my be solder balls, for example.

A semiconductor package in accordance with principles of inventive concepts may include a substrate having first and second surfaces which face each other; a first semiconductor chip formed on the first surface; connection terminals formed on the second surface, having first ends in contact with the second surface, and having partially concave side surfaces; and first and second encapsulants formed on the first and second surfaces and encapsulating the first semiconductor chip and the connection terminals, respectively, wherein second ends of the connection terminals protrude from the second encapsulant.

In accordance with principles of inventive concepts, each of the connection terminals may include a first external connection terminal and a second external connection terminal, wherein the first external connection terminal is formed on the second surface to penetrate the second encapsulant and has a first end in contact with the second surface, the second external connection terminal is attached to a second end of the first external connection terminal, a side surface of the first external connection terminal is surrounded by the second encapsulant, and a side surface of the second external connection terminal protrudes beyond the second encapsulant.

The second encapsulant may include first and second surfaces which face each other, wherein the first encapsulant surface contacts the second substrate surface, and the distance from the second substrate surface to the second encapsulant surface is substantially equal to the distance from the second substrate surface to the second end of the first external connection terminal.

The substrate may include a solder resist layer and ball lands formed on the second surface, the ball lands exposed by the solder resist layer, wherein the first end of a connection terminal contacts a ball land and the first and second encapsulants contain EMC. A second semiconductor chip may be formed on the second substrate surface, wherein the second semiconductor chip is encapsulated by the second encapsulant.

In accordance with principles of inventive concepts, an electronic device may include a substrate having first and second sides; a first semiconductor device mounted on one side of the substrate; a layer of encapsulant material formed on each side of the substrate and covering at least a portion of the semiconductor device; and a terminal that electrically contacts the substrate and extends from the substrate through a layer of encapsulant material. The terminal may include a waist region of lesser circumference than regions of the terminal on either side of the waist region. A second semiconductor device may be mounted on the opposite side of the substrate from the first semiconductor device. The layer of encapsulant material formed on the same surface of the substrate as the semiconductor device may leave the top surface of the semiconductor device exposed. A cellular telephone in accordance with principles of inventive concepts may include a semiconductor chip mounted on a substrate as just described.

### BRIEF DESCRIPTION OF THE DRAWINGS

The above and other aspects and features of inventive concepts will become more apparent by describing in detail exemplary embodiments thereof with reference to the attached drawings, in which:

FIG. 1 is a cross-sectional view of a semiconductor package in accordance with principles of inventive concepts;

FIG. 2 is a cross-sectional view of a second connection terminal shown in FIG. 1;

FIGS. 3 through 5 are cross-sectional views of intermediate structures illustrating a method of manufacturing a semiconductor package in accordance with principles of inventive concepts;

FIG. 6 is a cross-sectional view of an exemplary embodiment of a semiconductor package in accordance with principles of inventive concepts;

FIG. 7 is a cross-sectional view of an exemplary embodiment of a semiconductor package in accordance with principles of inventive concepts;

FIG. 8 is a cross-sectional view of an exemplary embodiment of a semiconductor package in accordance with principles of inventive concepts;

FIG. 9 is a cross-sectional view of an exemplary embodiment of a semiconductor package in accordance with principles of inventive concepts;

FIG. 10 is a cross-sectional view of an exemplary embodiment of a semiconductor package in accordance with principles of inventive concepts;

FIG. 11 is a cross-sectional view of an exemplary embodiment of a semiconductor package in accordance with principles of inventive concepts;

FIG. 12 is a plan view of an exemplary embodiment of a semiconductor system in accordance with principles of inventive concepts;

FIG. 13 is a block diagram of an exemplary embodiment of a semiconductor system in accordance with principles of inventive concepts;

FIG. 14 is a block diagram of an exemplary embodiment of a semiconductor system in accordance with principles of inventive concepts; and

FIG. 15 illustrates an exemplary embodiment of a electronic device in accordance with principles of inventive concepts.

### DETAILED DESCRIPTION OF THE EMBODIMENTS

Exemplary embodiments in accordance with principles of inventive concepts will now be described more fully with reference to the accompanying drawings, in which exemplary embodiments are shown. Exemplary embodiments in accordance with principles of inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions may be exaggerated for clarity. Like reference numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “bottom,” “below,” or “beneath” other elements or features would then be oriented “atop,” or “above,” the other elements or features. Thus, the exemplary terms “bottom,” or “below” can encompass both an orientation of above and below, top and bottom. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments in accordance with principles of inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In an exemplary embodiment in accordance with principles of inventive concepts, a semiconductor chip may be mounted on the “top” side of a substrate, with electrical connection made to wiring within the substrate through connection terminals. The connection terminals may be implemented as conductive balls situated on ball lands formed in the substrate, for example. Connection terminals on the opposite, “bottom,” side of the substrate may provide electrical communication between external circuitry and the semiconductor chip through wiring in the substrate, to the connection terminals on the semiconductor side of the substrate, and, through those connection terminals, to circuitry within the semiconductor chip. The substrate may include an insulating layer, with embedded wiring, and solder mask layers on either side of the insulating layer. The solder mask layers may be formed to allow electrical connection between connection terminals on either side of the substrate.

In an exemplary embodiment in accordance with principles of inventive concepts, the semiconductor chip and substrate upon which it is mounted may be encapsulated, for example, by two layers of material, one or both of which may include, or substantially constitute, epoxy molding compound (EMC). The upper layer of encapsulant material may completely surround the semiconductor chip or it may be flush with the upper surface of the semiconductor chip, leaving the top surface of the chip exposed, for example. The lower layer of encapsulant material may be thinner than the upper layer and may leave a portion of the lower connection terminals exposed, to allow for connection to external circuitry, for example.

The lower connection terminals may be formed of a plurality of conductive balls and may make contact with electrical wiring in the substrate through ball lands, as the upper connection terminals may similarly make contact with electrical wiring in the substrate. In an exemplary embodiment in accordance with principles of inventive concepts, the lower connection terminal may include two conductive balls, with the uppermost of the two having a relatively flat surface on top to allow for good contact with ball lands and a relatively flat surface on the bottom to allow for good contact with a second conductive ball. The lower of the two conductive balls may have a relatively flat top surface to allow for good contact with the first conductive ball. Because the lower connection terminal includes a plurality of conductive balls, the width of the terminals may be less than would otherwise be required for a contact terminal of the same height but made of a single conductive ball. Such a single-orb connection terminal would tend to have a broad waste region, as opposed to the relatively narrow, concave, region created by joining two conductive balls. As a result, lower connection terminals may be packed more closely than they might otherwise be packed.

The lower encapsulant layer in accordance with principles of inventive concepts may extend only part of the way along the length of the lower connection terminal: to the joint between two conductive balls that form the lower connection terminal, for example. In accordance with principles of inventive concepts, encapsulant layers on either side of the substrate operate to counterbalance thermal effects on the semiconductor packaging. That is, with the upper and lower encapsulation layers having similar thermal coefficients of expansion, warpage that might otherwise occur, with only one side of the semiconductor package encapsulated, for example, may be avoided.

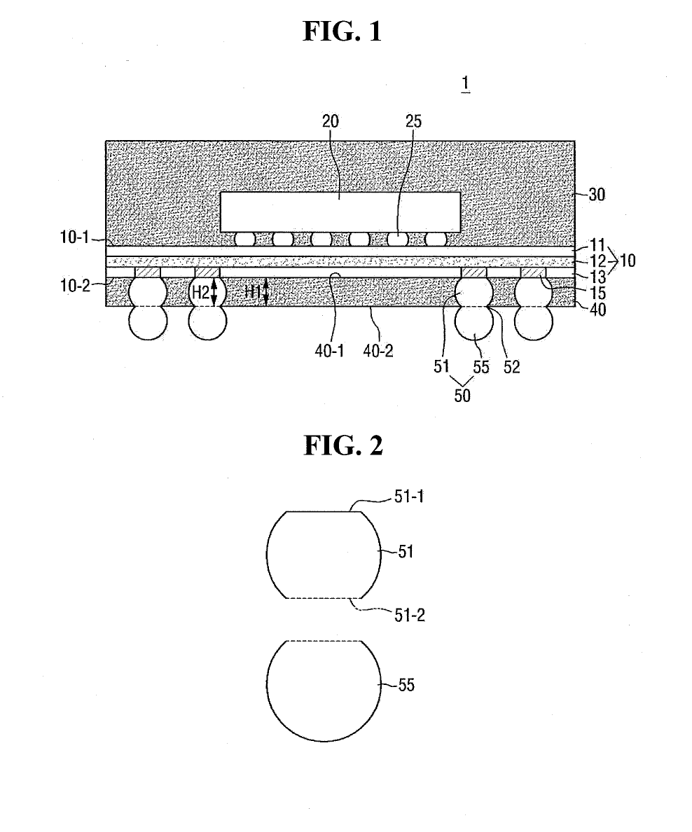

An exemplary embodiment of a semiconductor package in accordance with principles of inventive concepts will now be described with reference to FIGS. 1 and 2, which are, respectively, a cross sectional view of such a package, and a cross-sectional view of a terminal shown in FIG. 1.

The semiconductor package 1 may include a substrate 10, first and second encapsulants 30 and 40, and first and second connection terminals 25 and 50. The substrate 10 may be a printed circuit board (PCB), for example. The substrate 10 has a first surface 10-1, also referred to herein as upper surface 10-1, and a second surface 10-2, also referred to herein as lower surface 10-2, which are parallel to, and face, each other. In an exemplary embodiment in accordance with principles of inventive concepts, the substrate 10 may include first and second solder resist layers 11 and 13, respectively formed on “upper,” or first 10-1, and “lower,” or second 10-2, surfaces of core insulating layer 12, for example.

The first and second solder resist layers 11 and 13 may be formed of a solder-resist material, that is, a material that resists the taking of solder. The core insulating layer 12 may be formed of an insulating material such as may be used in the formation of printed circuit boards, for example.

Ball lands 15 may be formed on the second surface 10-2 of the substrate 10. The ball lands 15 may be exposed by the second solder resist layer 13. Although not shown in FIG. 1, ball lands may also be formed on the first surface 10-1 of the substrate 10.

A first semiconductor chip 20 may be mounted on the first surface 10-1 of the substrate 10. The first semiconductor chip 20 may be mounted on the first surface 10-1 of the substrate 10 by flip-chip bonding, for example. The first semiconductor chip 20 may be electrically connected to the substrate 10 by the first connection terminals 25. The first semiconductor chip 20 may be a memory chip, such as a dynamic random access memory (DRAM) or a flash memory, or a logic chip, a controller, or other semiconductor chip, for example.

The first connection terminals 25 may be conductive balls or solders balls, for example. The first connection terminals 25 may be implemented as conductive bumps, conductive spacers, or pin grid arrays (PGAs), for example.

In an exemplary embodiment in accordance with principles of inventive concepts, the first encapsulant 30 is formed on the first, “upper,” surface 10-1 of the substrate 10 to encapsulate the first semiconductor chip 20. The first encapsulant 30 may be formed to cover the first surface 10-1 of the substrate 10 and the first semiconductor chip 20, and a space between the first semiconductor chip 20 and the first surface 10-1 of the substrate 10 may be filled with the first encapsulant 30, for example. In an exemplary embodiment in accordance with principles of inventive concepts, the first encapsulant 30 may be formed to expose a top surface of the first semiconductor chip 20.

The second encapsulant 40 may be formed on the second, “lower,” or “bottom” surface 10-2 of the substrate 10 to encapsulate the second connection terminals 50. The second encapsulant 40 may encapsulate only a portion of each of the second connection terminals 50, and a remaining region, or portion of each of the second connection terminals 50 may protrude from the second encapsulant 40, for example. In an exemplary embodiment in accordance with principles of inventive concepts, the second encapsulant 40 may be formed to cover the second surface 10-2 of the substrate 10 and surround a side surface of a first external connection terminal 51 (also referred to herein as connection terminal portion 51), without surrounding a side surface of a second external connection terminal 55 (also referred to herein as connection terminal portion 55).

In an exemplary embodiment in accordance with principles of inventive concepts, the second encapsulant 40 has third and fourth parallel surfaces 40-1 and 40-2, respectively, which face each other. The third surface 40-1 may contact the second surface 10-2 of the substrate 10, for example. The fourth surface 40-2 of the second encapsulant 40 and a second end 51-2 of the first external connection terminal 51 may be formed simultaneously by a grinding process, for example, which will be described later. That is, the fourth surface 40-2 of the second encapsulant 40 and the second end 51-2 of the first external connection terminal 51 may be ground surfaces. In an exemplary embodiment in accordance with principles of inventive concepts, the distance H1 from the second surface 10-2 of the substrate 10 to the fourth surface 40-2 of the second encapsulant 40 may be substantially equal to the distance H2 from the second surface 10-2 of the substrate 10 to the second end 51-2 of the first external connection terminal 51. The distances H1 and H2 may be made equal using a grinding process, as will be described in greater detail in the discussion related to upcoming FIGs.

In an exemplary embodiment in accordance with principles of inventive concepts, the first encapsulant 30 may be thicker than the second encapsulant 40. The first and second encapsulants 30 and 40 may contain epoxy molding compound (EMC), for example.

The second connection terminals 50 may be formed on the second surface 10-2 of the substrate 10, with, for example, first ends of the second connection terminals 50 contacting the ball lands 15. Second ends of the second connection terminals 50 may protrude from the second encapsulant 40. In addition, a region 52 of a side surface of each of the second connection terminals 50 may be concave. The side surface of each of the second connection terminals 50 may have an uneven or embossed shape.

Each of the second connection terminals 50 may include the first external connection terminal 51 and the second external connection terminal 55. The first external connection terminal 51 may be formed on the second surface 10-2 of the substrate 10 to penetrate the second encapsulant 40, and a first end 51-1 of the first external connection terminal 51 may contact the second surface 10-2 of the substrate 10. The first end 51-1 of the first external connection terminal 51 may contact a ball land 15. A side surface of the first external connection terminal 51 may be surrounded by the second encapsulant 40. The second external connection terminal 55 may be attached to the second end 51-2 of the first external connection terminal 51. In an exemplary embodiment in accordance with principles of inventive concepts, at leas a portion of a side surface of the second connection terminal 55 may project from the second encapsulant 40. That is, a portion of each of the second connection terminals 50 which protrudes from the second encapsulant 40 may be, in whole or in part, the second external connection terminal 55.

Because, in this exemplary embodiment in accordance with principles of inventive concepts, the second end 51-2 of the first external connection terminal 51 is a ground surface as described above, it may be a flat surface. The second external connection terminal 55 may contact the second end 51-2 of the first external connection terminal 51. The second external connection terminal 55 may be attached to the first external connection terminal 51 by a reflow process, for example. The region 52 in which the first external connection terminal 51 and the second external connection terminal 51 contact each other may be relatively concave, forming a relatively thin “waist” region in the connection terminal 50. The side surface of the first external connection terminal 51 and the side surface of the second external connection terminal 55 may be linked to form an uneven or embossed shape.

Each of the second connection terminals 50 may have a structure in which the first external connection terminal 51 and the second external connection terminal 55 are stacked sequentially on a corresponding one of the ball lands 15 of the substrate 10, for example.

The second connection terminals 50 and the first and second external connection terminals 51 and 55 may be conductive balls, such as solder balls, for example. Additionally, the second connection terminals 50 and the first and second external connection terminals 51 and 55 may be any one of conductive bumps, conductive spacers, or PGAs, for example.

As described above, the first and second surfaces 10-1 and 10-2 of the substrate 10 of the semiconductor package 1 according to an exemplary embodiment in accordance with principles of inventive concepts are molded by the first and second encapsulants 30 and 40, respectively. The double-side molded substrate 10 included in the semiconductor package 1 can reduce warpage of the semiconductor package 1 and thereby increase the reliability of the packaged semiconductor. That is, if only one surface of a substrate is molded by an encapsulant, a temperature change may cause a semiconductor package to warp due to a coefficient of thermal expansion (CTE) mismatch between the substrate and the encapsulant. In the semiconductor package 1, however, both surfaces 10-1 and 10-2 of the substrate 10 are molded by the first and second encapsulants 30 and 40 with the same CTE. As a result, even if the substrate 10 has a different CTE from that of the first and second encapsulants 30 and 40, because the first and second encapsulants 30 and 40, having substantially the same CTE are disposed on both surfaces 10-1 and 10-2 of the substrate 10, a warpage balance can be secured, or, in other words, warpage of the semiconductor package may be reduced or avoided altogether.

As described above, each of the second connection terminals 50 of the semiconductor package 1 according to a first exemplary embodiment in accordance with principles of inventive concepts includes first and second external connection terminals 51 and 55. The previously-described, relatively narrow, “waist” region at the junction of first and second connection terminals 51 and 55 may allow for fine-pitch connection terminal placement, for example. In order for the semiconductor package 1 to be used in a “package-on-package” configuration, second terminals 50 extend a minimal length beyond the substrate 10. As previously described, a connection terminal comprising a single conductive ball may be substantially wider than a multi-ball connection terminal. That is, surface tension of the conductive ball material may expand the material during formation, and, as a result, a multi-ball connection terminal may be slimmer than a single-ball connection terminal, for a given connection terminal length. The slimmer profile of a multi-ball connection terminal in accordance with principles of inventive concepts may, therefore, allow for a “package-on-package” configuration that employs a relatively fine pitch.

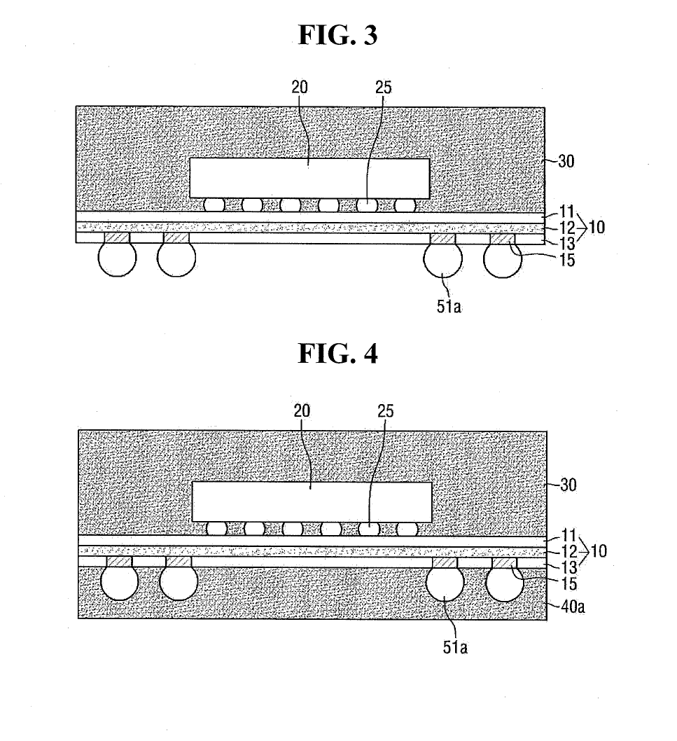

A method of manufacturing the semiconductor package 1 according to an exemplary embodiment in accordance with principles of inventive concepts will now be described with reference to FIGS. 1 and 3 through 5. FIGS. 3 through 5 are cross-sectional views of intermediate structures illustrating a method of manufacturing a semiconductor package 1 in accordance with principles of inventive concepts.

Referring to FIG. 3, the first semiconductor chip 20 may be formed on the first surface 10-1 of the substrate 10 and may be encapsulated by the first encapsulant 30. A first external connection terminal 51 a may be formed on the second surface 10-2 of the substrate 10. Specifically, a first external connection terminal 51a may be attached to each of the balls lands 15 of the substrate 10.

Referring to FIG. 4, a second encapsulant 40a may be formed on the second surface 10-2 of the substrate 10. Specifically, the second encapsulant 40a may be formed to cover the second surface 10-2 of the substrate 10 and the first external connection terminal 51a.

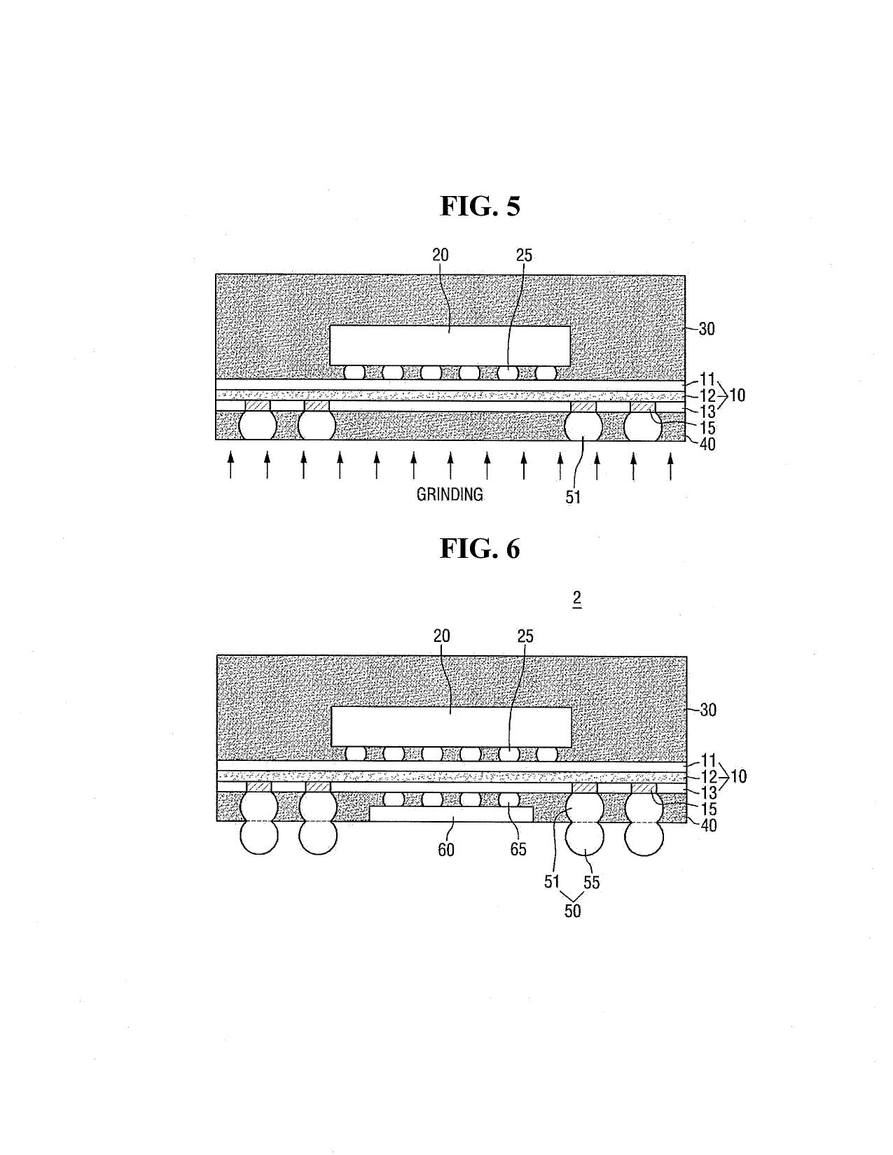

Referring to FIG. 5, a portion of the second encapsulant 40a may be removed, by grinding, for example, until the first external connection terminal 51 a is exposed. In the process of removing a portion of the second encapsulant 40a, a portion of the first external connection terminal 51 a may also be removed, by grinding for example, to yield a relatively flat surface on the external connection terminal 51a. The resulting flat surface, shown in FIG. 5, may be advantageous for mating with a second external connection terminal 55.

Because the second encapsulant 40a and the first external connection terminal 51a are ground simultaneously, the distance H1 from the second surface 10-2 of the substrate 10 to the fourth surface 40-2 of the second encapsulant 40 may be substantially equal to the distance 112 from the second surface 10-2 of the substrate 10 to the second end 51-2 of the first external connection terminal 51, as described in the discussion related to FIGS. 1 and 2.

Referring to FIG. 1, the second external connection terminal 55 may be attached to the second end 51-2 of the first external connection terminal 51 and may be securely coupled to the first external connection terminal 51 by a reflow process, for example.

A semiconductor package according to a second exemplary embodiment in accordance with principles of inventive concepts will now be described with reference to FIG. 6. For simplicity and clarity of description, the following description will focus on differences between the semiconductor package 1 according to the first exemplary embodiment and the semiconductor package 2 according to a second exemplary embodiment in accordance with principles of inventive concepts.

Referring to FIG. 6, unlike the exemplary embodiment of semiconductor package 1 (see FIG. 1), the semiconductor package 2 according to a second embodiment in accordance with principles of inventive concepts may include a second semiconductor chip 60 formed on the second surface 10-2 of substrate 10. The second semiconductor chip 60 may be mounted on the second surface 10-2 of the substrate 10 via third connection terminals 65 by flip-chip bonding, for example. The second semiconductor chip 60 may be enclosed by a second encapsulant 40, and a space between the second semiconductor chip 60 and the second surface 10-2 of the substrate 10 may be filled with the second encapsulant 40. A top surface of the second semiconductor chip 60, that is, the surface opposite the surface connected through third connection terminals 65 to substrate 10, may be exposed by the second encapsulant 40, for example, or it may also be covered with the second encapsulant 40.

Because the semiconductor package 2 according to a second exemplary embodiment includes the second semiconductor chip 60 formed on the second surface 10-2 of the substrate 10 and enclosed by the second encapsulant 40, it may have a low profile. That is, with a second semiconductor chip conveniently placed between connection terminals 65, the overall thickness of the semiconductor package 2 may be less than a multi-chip package that stacks a plurality of chips on a single surface, such as the first surface 10-1 first surface 10-1 of the substrate 10.

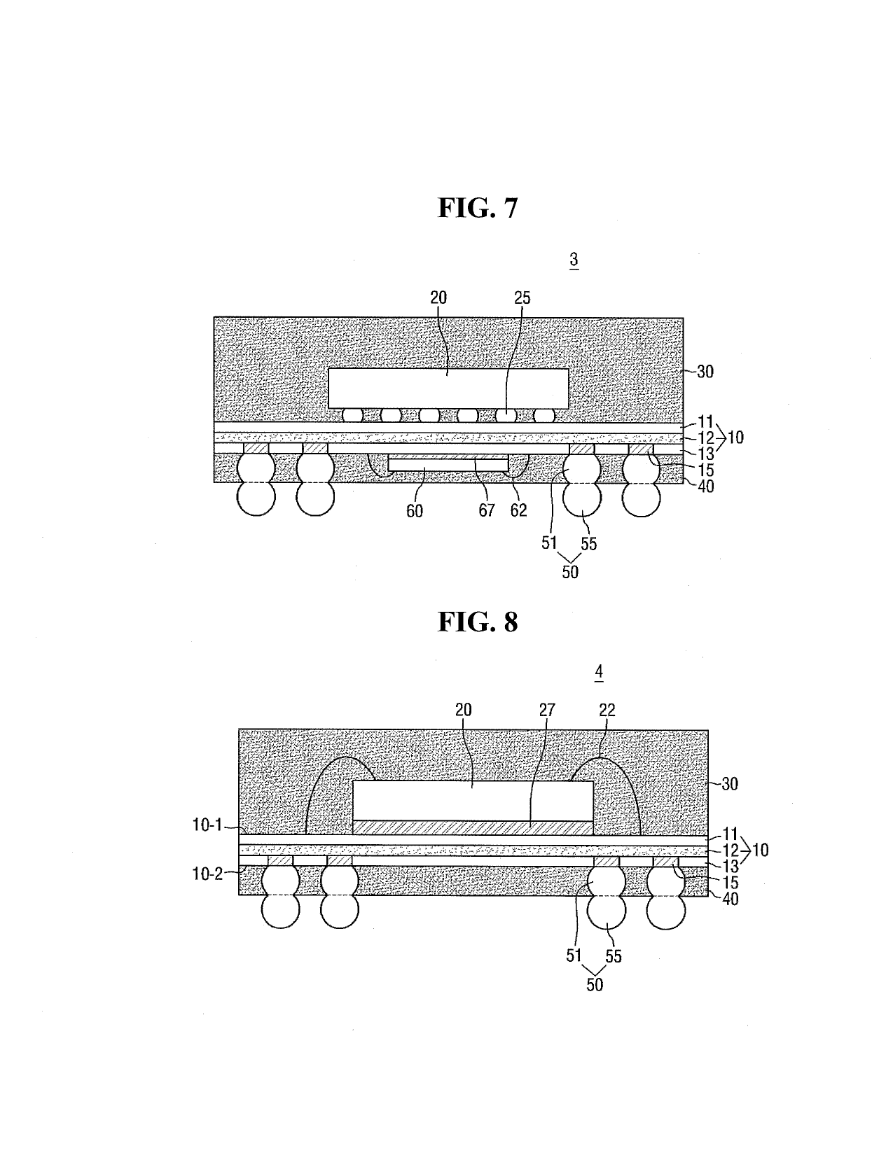

A third exemplary embodiment of a semiconductor package in accordance with principles of inventive concepts will now be described with reference to FIG. 7. For simplicity and clarity of description, the following description will focus on differences between the second and third embodiments of semiconductor packages in accordance with principles of inventive concepts.

FIG. 7 is a cross-sectional view of an exemplary embodiment of a semiconductor package 3 in accordance with principles of inventive concepts which may include a second semiconductor chip 60 attached onto a second surface 10-2 of a substrate 10 by an adhesive 67. The second semiconductor chip 60 may be electrically connected to the substrate 10, and to circuitry within substrate 10, by wires 62. In an exemplary embodiment in accordance with principles of inventive concepts, the second semiconductor chip 60 may be encapsulated by a second encapsulant 40.

A fourth exemplary embodiment of a semiconductor package in accordance with principles of inventive concepts will now be described with-reference to FIG. 8. For simplicity and clarity, the following description will focus primarily on differences between the first exemplary embodiment (semiconductor package 1) and the current, fourth exemplary embodiment of a semiconductor package 4 in accordance with principles of inventive concepts.

FIG. 8 is a cross-sectional view of a semiconductor package 4 in which a first semiconductor chip 20 may be attached onto a first surface 10-1 of a substrate 10 by an adhesive 27 and electrically connected to the substrate 10, and circuitry within the substrate 10, by wires 22. In an exemplary embodiment in accordance with principles of inventive concepts, the first semiconductor chip 20 and wires 22 may be encapsulated by a first encapsulant 30.

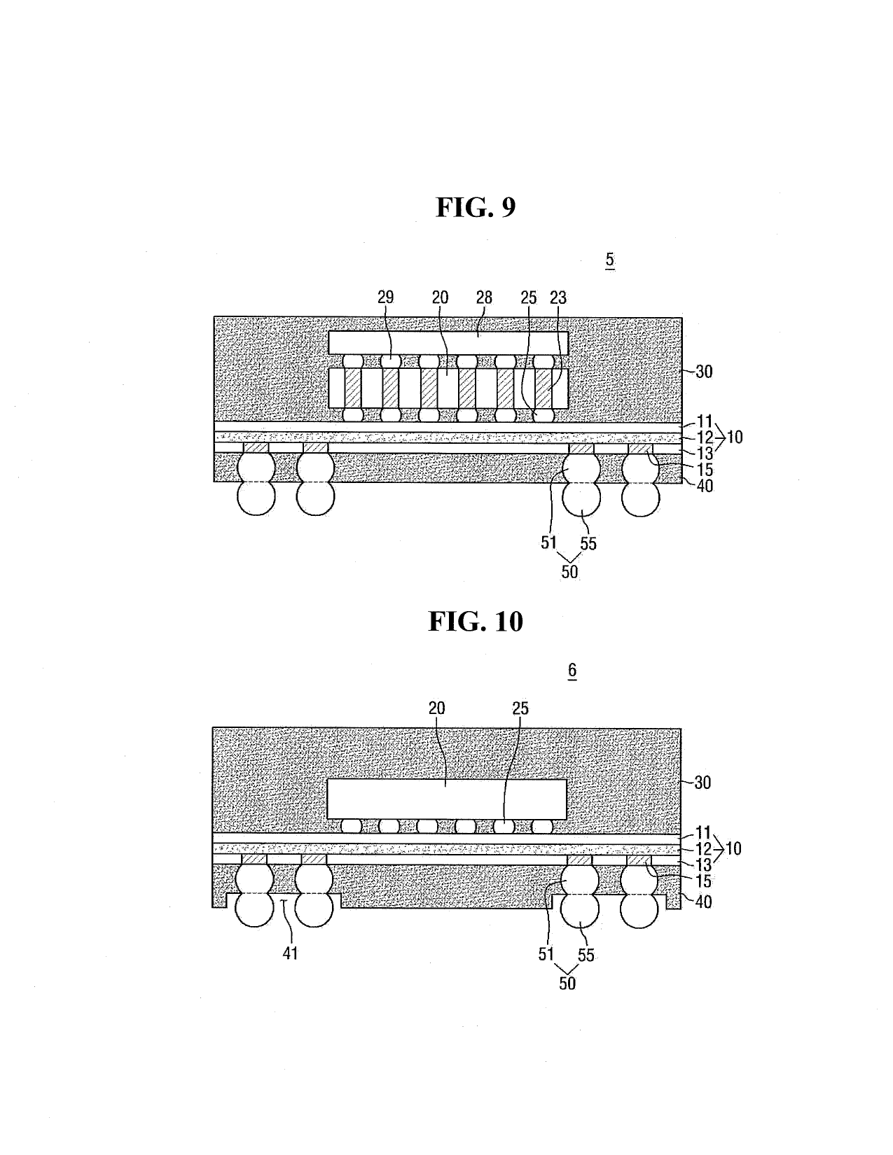

A fifth exemplary embodiment of a semiconductor package in accordance with principles of inventive concepts will now be described with reference to FIG. 9. For simplicity and clarity, the following description will focus on differences between the first exemplary embodiment of a semiconductor package and this, the fifth, exemplary embodiment of a semiconductor package in accordance with principles of inventive concepts.

FIG. 9 is a cross-sectional view of a semiconductor package 5 in accordance with principles of inventive concepts but, unlike in the semiconductor package 1, first and third semiconductor chips 20 and 28 may be formed on a first surface 10-1 of a substrate 10. In this exemplary embodiment, the first and third semiconductor chips 20 and 28 may be sequentially stacked on the first surface 10-1 of the substrate 10. First through-electrodes 23 may be formed in the first semiconductor chip 20. The first through electrodes 23 may be through-silicon vias, for example. The third semiconductor chip 28 may be electrically connected to the first semiconductor chip 20 through electrodes 23 of the first semiconductor chip 20 by fourth connection terminals 29, for example.

A sixth exemplary embodiment of a semiconductor package in accordance with principles of inventive concepts will now be described with reference to FIGS. 4 and 10. For simplicity and clarity, the following description will focus on differences between the semiconductor package 1 according to the first embodiment of the present inventive concept and the current, sixth, exemplary embodiment.

FIG. 10 is a cross-sectional view of a sixth exemplary embodiment of a semiconductor package 6 in accordance with principles of inventive concepts. Referring to FIGS. 4 and 10, to manufacture the semiconductor package 6 according to the sixth embodiment, only a portion of the surface of a second encapsulant 40a may be ground. Only a region of the second encapsulant 40a in which first external connection terminals 51 are formed may be ground, yielding trenches 41 that expose the first external connection terminals 51, for example. In this exemplary embodiment, second external connection terminals 55 may be formed in each trench 41 to contact the first external connection terminals 51, for example.

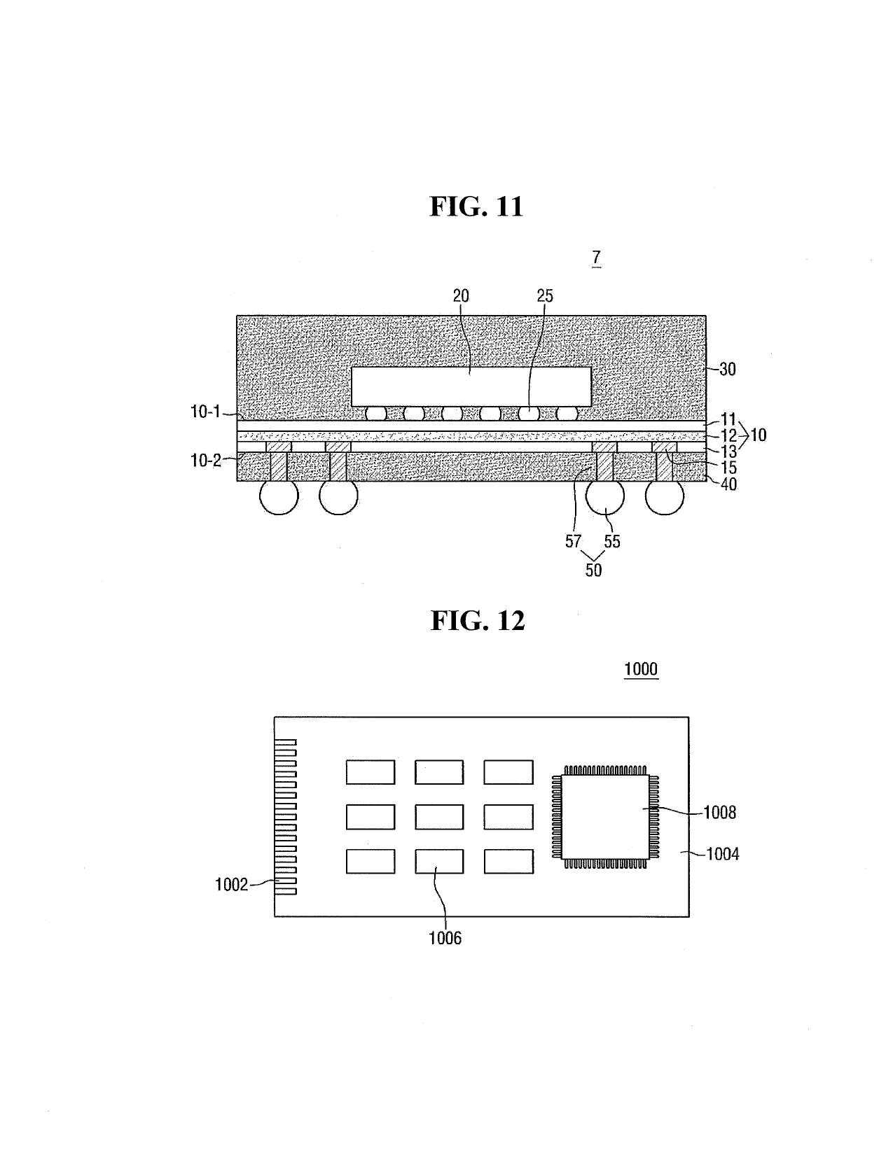

A seventh exemplary embodiment of a semiconductor package in accordance with principles of inventive concepts will now be described with reference to FIG. 11. For simplicity and clarity, the following description will focus on differences between the first and seventh exemplary embodiments, package 1 and package 7, in accordance with principles of inventive concepts.

FIG. 11 is a cross-sectional view of a seventh exemplary embodiment of a semiconductor package 7 in accordance with principles of inventive concepts. Unlike the exemplary embodiment of FIG. 1 (semiconductor package 1), the semiconductor package 7, may include second through-electrodes 57 formed by forming vias in a second encapsulant 40 and filling the vias with a conductive material. The second through electrodes 57 may be, for example, through-mold vias. Second external connection terminals 55 may be formed to respectively contact the second through-electrodes 57, for example.

Semiconductor systems in accordance with principles of inventive concepts will now be described with reference to FIGS. 12 through 15.

FIG. 12 is a plan view of an exemplary embodiment of a semiconductor system 1000 in accordance with principles of inventive concepts. The semiconductor system 1000 may be a package module that may include one or more semiconductor packages in accordance with principles of inventive concepts, such as previously described herein. The semiconductor system 1000 may include a module substrate 1004, which includes external connection terminals 1002, and semiconductor devices 1006 and 1008. Although the semiconductor device 1008 shown in the drawing is a quad flat package (QFP) packages in accordance with principles of inventive concepts are not limited thereto. Either one, or both, of the semiconductor devices 1006 and 1008 may be formed using a semiconductor package in accordance with principles of inventive concepts, such as one of the exemplary packages described above with reference to FIGS. 1 through 11. Either of the semiconductor devices 1006 and 1008 may be formed using a semiconductor package that includes a substrate having a first surface and a second surface which face each other, a first semiconductor chip formed on the first surface, a first encapsulant formed on the first surface and encapsulating the first semiconductor chip, a second encapsulant formed on the second surface, first external connection terminals formed on the second surface to penetrate the second encapsulant and having first ends in contact with the second surface, and second external connection terminals attached to second ends of the first external connection, for example.

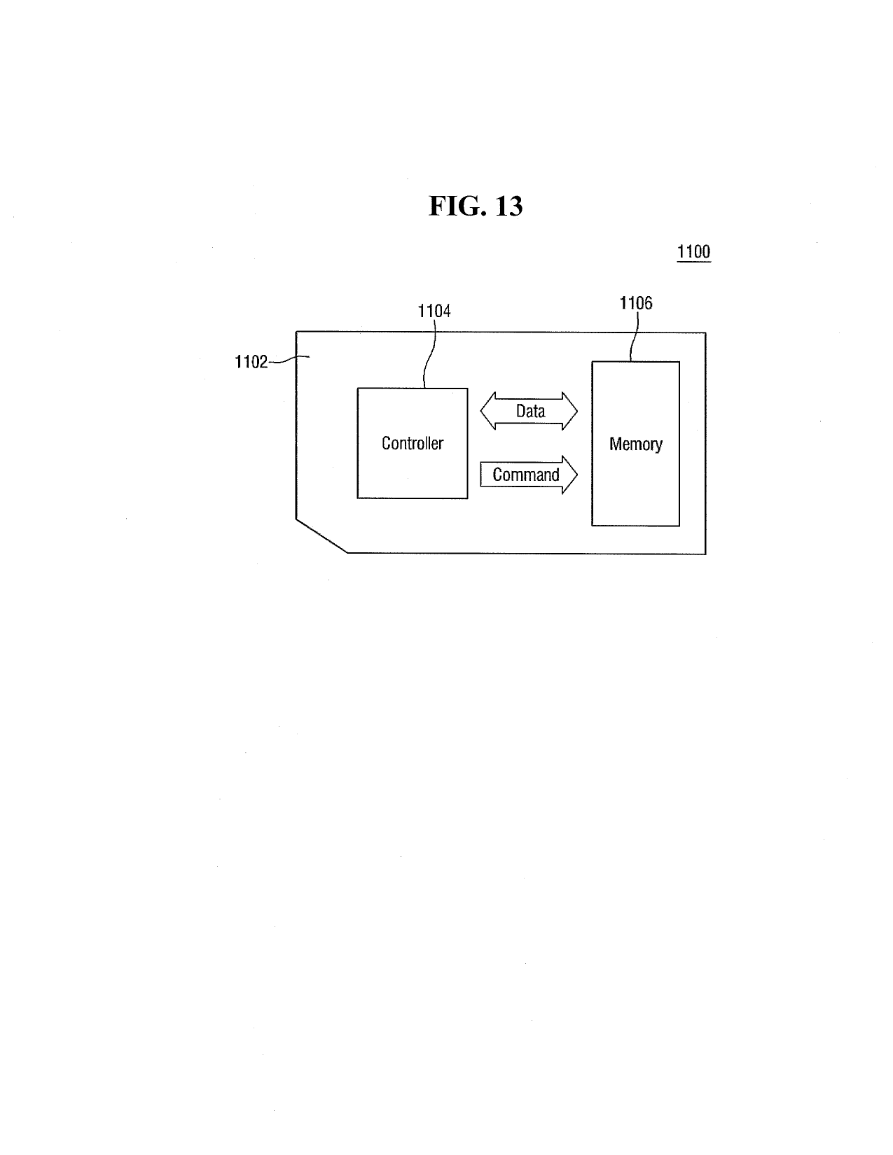

FIG. 13 is a block diagram of a semiconductor system 1100 in accordance with principles of inventive concepts, which may, for example, be a memory card. The semiconductor system 1100 may include a controller 1104 and a memory 1106 within a housing 1102. The controller 1104 and the memory 1106 may exchange electrical signals representing data or control signals, for example, with each other, with the controller 1104 writing data to or reading data from the memory 1106. The semiconductor system 1100 may store data in the memory 1106 from, or output data from the memory 1106 to, an external circuit. Either one, or both, of the controller 1104 and the memory 1106 may be packaged in accordance with principles of inventive concepts.

A semiconductor system 1100 in accordance with principles of inventive concepts may be combined with other components to form any of various portable devices in accordance with principles of inventive concepts, for example. The semiconductor system 1100 may be implemented as a multimedia card (MMC) or a secure digital (SD) card, for example.

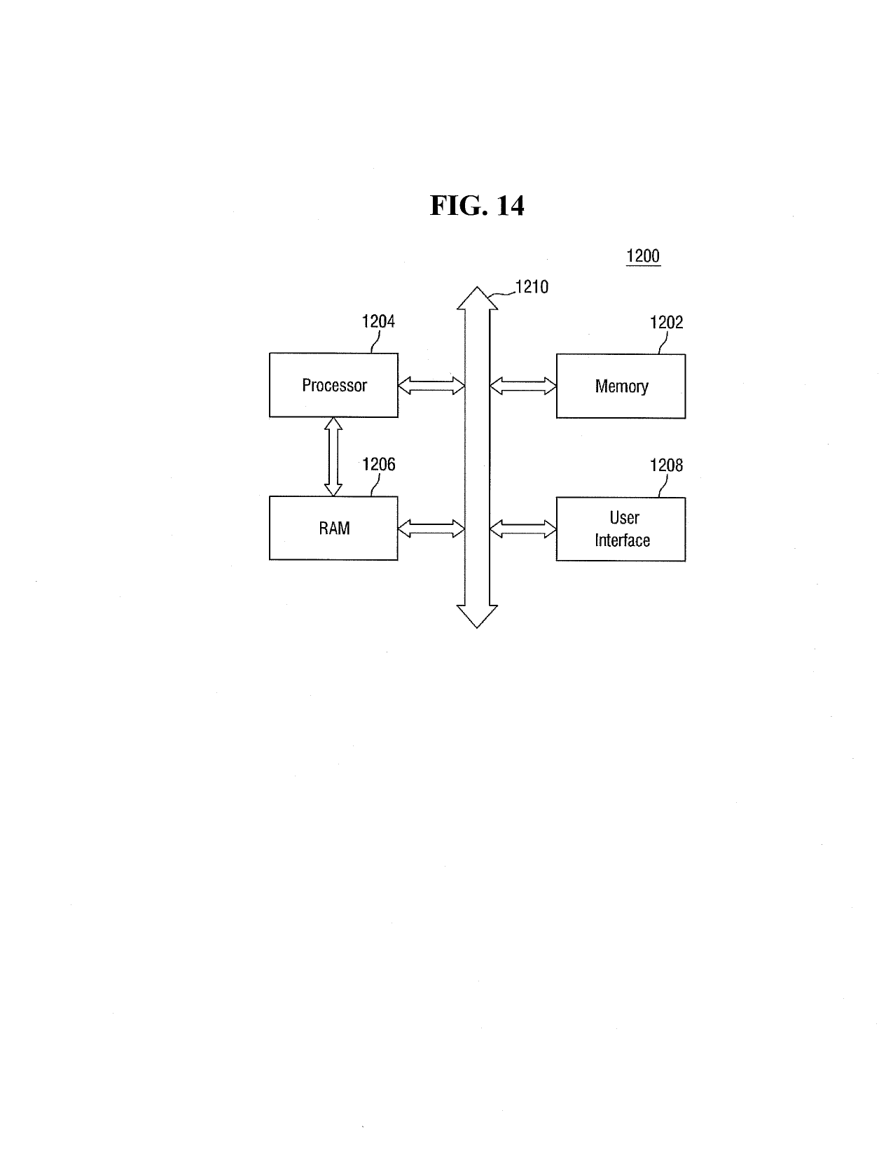

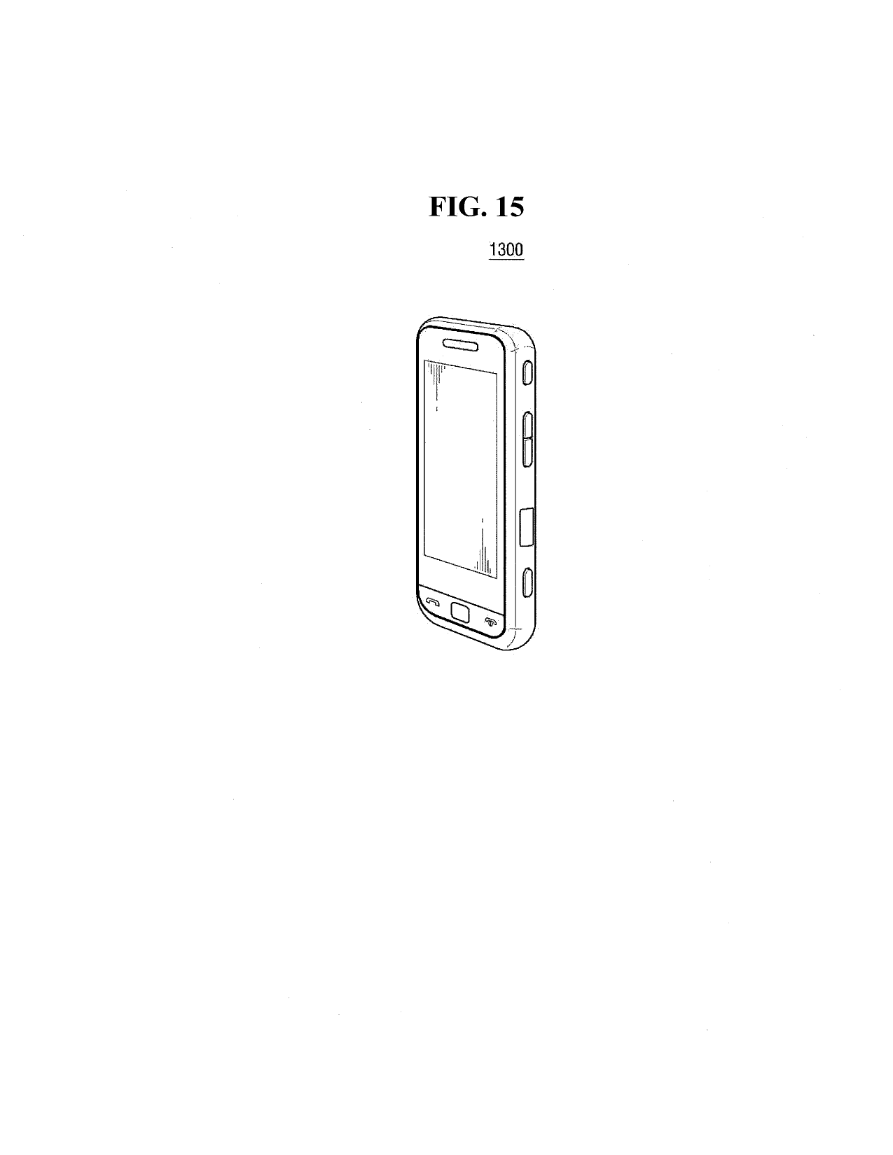

FIG. 14 is a block diagram of an exemplary embodiment of a semiconductor system 1200 in accordance with principles of inventive concepts. FIG. 15 illustrates an exemplary embodiment of an electronic device in accordance with principles of inventive concepts which may include a semiconductor chip packaged according to principles of inventive concepts and which may include a semiconductor system, such as the semiconductor system 1200, in accordance with principles of inventive concepts.

Referring to FIG. 14, a semiconductor system 1200 in accordance with principles of inventive concepts may include a memory system 1202, a processor 1204, a random access memory (RAM) 1206, and a user interface 1208. These elements may exchange data with each other using a bus 1210. The processor 1204 may execute a program and control the semiconductor system 1200. The. RAM 1206 may be used as a working memory of the processor 1204. The processor 1204 and the RAM 1206 may be included in one package. For example, a logic chip having the processor 1204 and a memory chip having the RAM 1206 may be included in a system-in package and may communicate wirelessly with each other. The user interface 1208 may be used to input or output data to/from the semiconductor system 1200. The memory system 1202 may store codes needed to operate the processor 1204, data processed by the processor 1204, or data input from an external source. The memory system 1202 may include a controller and a memory and may be configured in substantially the same or similar manner as the memory card 1300 of FIG. 13, for example.

The semiconductor system 1200 in accordance with principles of inventive concepts may be incorporated in or employed by any of a variety of electronic controllers and systems. For example, the semiconductor system 1200 may be employed by a mobile phone 1500 in accordance with principles of inventive concepts (see FIG. 15). The semiconductor system 1200 can also be applied to portable game players, portable notebooks, MP3 players, navigation devices, solid-state disks (SSDs), vehicles, and household appliances, for example.

While the present inventive concept has been particularly shown and described with reference to exemplary embodiments thereof, it will be understood that various changes in form and details may be made therein without departing from the spirit and scope of inventive concepts as defined by the following claims. It is therefore desired that the present embodiments be considered in all respects as illustrative and not restrictive, reference being made to the appended claims rather than the foregoing description to indicate the scope of inventive concepts.

1. A semiconductor package comprising:
a substrate having first and second surfaces which face each other;
a first semiconductor chip mounted on the first surface;
a first encapsulant formed on the first surface and encapsulating at least a portion of the first semiconductor chip;
a second encapsulant formed on the second surface;
first external connection terminals formed on the second surface to penetrate the second encapsulant and having first ends in contact with the second surface; and
second external connection terminals attached to second ends of the first external connection terminals, respectively.

2. The semiconductor package of claim 1, wherein the second encapsulant has first and second surfaces which face each other, wherein the first encapsulant surface contacts the second substrate surface, and the distance from the second substrate surface to the second encapsulant surface is equal to the distance from the second substrate surface to the second ends of the first external connection terminals.

3. The semiconductor package of claim 2, wherein side surfaces of the first external connection terminals are surrounded by the second encapsulant, and side surfaces of the second external connection terminals are clear of the second encapsulant.

4. The semiconductor package of claim 1, wherein the substrate comprises a ball land formed on the second surface, wherein the first end of a first external connection terminal contacts the ball land and the first and second external connection terminals are stacked sequentially on the ball land.

5. The semiconductor package of claim 1, wherein the second end of a first external connection terminal is a flat surface.

6. The semiconductor package of claim 1, wherein the side surfaces of the first external connection terminals and the side surfaces of the second external connection terminals are linked to form uneven shapes.

7. The semiconductor package of claim 1, wherein the substrate comprises a solder resist layer formed on the second surface, and the first and second encapsulants contain epoxy molding compound (EMC).

8. The semiconductor package of claim 1, further comprising a second semiconductor chip formed on the second surface, wherein the second semiconductor chip is encapsulated by the second encapsulant.

9. The semiconductor package of claim 1, wherein the first encapsulant is thicker than the second encapsulant.

10. The semiconductor package of claim 1, wherein the first and second external connection terminals are solder balls.

11. A semiconductor package comprising:
a substrate having first and second surfaces which face each other;
a first semiconductor chip formed on the first surface;
connection terminals formed on the second surface, having first ends in contact with the second surface, and having partially concave side surfaces; and
first and second encapsulants formed on the first and second surfaces and encapsulating the first semiconductor chip and the connection terminals, respectively, wherein second ends of the connection terminals protrude from the second encapsulant.

12. The semiconductor package of claim 11, wherein each of the connection terminals comprises a first external connection terminal and a second external connection terminal, wherein the first external connection terminal is formed on the second surface to penetrate the second encapsulant and has a first end in contact with the second surface, the second external connection terminal is attached to a second end of the first external connection terminal, a side surface of the first external connection terminal is surrounded by the second encapsulant, and a side surface of the second external connection terminal protrudes beyond the second encapsulant.

13. The semiconductor package of claim 12, wherein the second encapsulant includes first and second surfaces which face each other, wherein the first encapsulant surface contacts the second substrate surface, and the distance from the second substrate surface to the second encapsulant surface is equal to the distance from the second substrate surface to the second end of the first external connection terminal.

14. The semiconductor package of claim 11, wherein the substrate comprises a solder resist layer and ball lands formed on the second surface, the ball lands exposed by the solder resist layer, wherein the first end of a connection terminal contacts a ball land and the first and second encapsulants contain EMC.

15. The semiconductor package of claim 11, further comprising a second semiconductor chip formed on the second substrate surface, wherein the second semiconductor chip is encapsulated by the second encapsulant.

16. An apparatus, comprising:
a substrate having first and second sides;
a first semiconductor device mounted on one side of the substrate;
a layer of encapsulant material formed on each side of the substrate and covering at least a portion of the semiconductor device; and
a terminal that electrically contacts the substrate and extends from the substrate through a layer of encapsulant material.

17. The apparatus of claim 16, wherein the terminal includes a waist region of lesser circumference than regions of the terminal on either side of the waist region.

18. The apparatus of claim 16, further comprising a second semiconductor device mounted on the opposite side of the substrate from the first semiconductor device.

19. The apparatus of claim 16 wherein the layer of encapsulant material formed on the same surface of the substrate as the semiconductor device leaves the top surface of the semiconductor device exposed.

20. A cellular telephone including the apparatus of claim 16.
